(19) United States
(12) Patent Application Publication
(10) Pub. No.: US 2023/0350039 A1
(43) Pub. Date: Nov. 2, 2023

(54) CIRCUIT FOR CONTROLLING AN ULTRASONIC TRANSDUCER

(71) Applicant: MODULEUS, TOUR (FR)

(72) Inventor: Pascal CHATAIN, TOURS (FR)

(21) Appl. No.: 17/925,256

(22) PCT Filed: May 4, 2021
(86) PCT No.: PCT/EP2021/061706

§ 371 Date: Nov. 14, 2022

(30) Foreign Application Priority Data
May 13, 2020 (FR) FR2004714

(51) Int. Cl. G01S 7/52; H03M 1/18

(52) U.S. Cl. CPC G01S 7/52033; H03M 1/18; G01S 15/8906

(57) ABSTRACT

A circuit for controlling an ultrasonic transducer, includes a receive circuit having an input terminal and an analog dynamic range compression circuit. The input terminal is intended to be coupled to an electrode of the transducer.

### RELATED APPLICATIONS

The present patent application claims the priority benefit of French patent application FR20/04714 which is herein incorporated by reference.

### FIELD

The present application concerns the field of ultrasonic imaging, and more particularly aims at an electronic circuit for controlling an ultrasonic transducer of an ultrasonic imaging device.

### BACKGROUND

An ultrasonic imaging device conventionally comprises a plurality of ultrasonic transducers, for example, arranged in a one-dimensional or in a two-dimensional array. In operation, the transducer assembly is arranged opposite a body which is desired to be imaged. The device further comprises an electronic control circuit capable of applying electric excitation signals to the transducers to cause the emission of ultrasonic waves by the transducers, towards the body to be analyzed. The ultrasonic waves emitted by the transducers are reflected by the body to be analyzed (by its internal and/or surface structure), and then return to the transducers, which convert them back into electric signals. The electric response signals are read by the electronic control circuit and may be stored and analyzed to deduce therefrom information relative to the studied body.

It would be desirable to at least partly improve certain aspects of known ultrasonic transducer control circuits.

### SUMMARY OF THE INVENTION

For this purpose, an embodiment provides a circuit for controlling an ultrasonic transducer, comprising a receive circuit having an input terminal intended to be coupled to an electrode of the transducer, said receive circuit comprising an analog dynamic range compression circuit.

According to an embodiment, the receive circuit further comprises an analog-to-digital converter, the analog dynamic range compression circuit having an input node coupled to the input terminal of the receive circuit and an output node coupled to an input node of the analog-to-digital converter.

According to an embodiment, the circuit further comprises, at the output of the analog-to-digital converter, a digital correction circuit configured to apply to the output signal of the analog-to-digital converter a digital gain variable according to the amplitude of the signal, compensating for the analog gain variation applied by the analog dynamic range compression circuit.

According to an embodiment, the analog dynamic range compression circuit is a non-linear amplification circuit having a symmetrical transfer function, said transfer function being, for positive input signals, an increasing monotonous function having its derivative monotonously decreasing according to the amplitude of the input signal.

According to an embodiment, the dynamic range compression circuit has a transfer function of hyperbolic arcsine, arc tangent, log, or sine type.

According to an embodiment, the dynamic range compression circuit comprises a plurality of analog amplifiers and an adder of analog voltages.

According to an embodiment, the analog amplifiers are coupled in series, each analog amplifier having an output node coupled to a corresponding input node of the voltage adder.

According to an embodiment, each analog amplifier has its output node coupled to the corresponding input node of the voltage adder via a switch.

According to an embodiment, the analog amplifiers are linear amplifiers and have all substantially the same gain.

According to an embodiment, the analog amplifiers are connected by their respective input nodes, each analog amplifier having an output node coupled to a corresponding input node of the voltage adder.

According to an embodiment, each analog amplifier has its output node coupled to the corresponding input node of the voltage adder via a switch.

According to an embodiment, the analog amplifiers are linear amplifiers and all have different gains.

### BRIEF DESCRIPTION OF THE DRAWINGS

The foregoing features and advantages, as well as others, will be described in detail in the rest of the disclosure of specific embodiments given by way of illustration and not limitation with reference to the accompanying drawings, in which:

FIG. 1 schematically illustrates, in the form of blocks, an example of a circuit for controlling an ultrasonic imaging device;

FIG. 2 schematically and partially illustrates, in the form of blocks, an example of a circuit for controlling an ultrasonic transducer according to an embodiment;

FIG. 3 is a diagram illustrating an example of transfer function of a dynamic range compression circuit of the control circuit of FIG. 2;

FIG. 4 is a diagram illustrating another example of transfer function of a dynamic range compression circuit of the control circuit of FIG. 2;

FIG. 5 schematically illustrates in the form of blocks an example of embodiment of a dynamic range compression circuit of the control circuit of FIGS. 2; and

FIG. 6 schematically shows in the form of blocks another example of embodiment of a dynamic range compression circuit of the control circuit of FIG. 2.

### DESCRIPTION OF THE EMBODIMENTS

Like features have been designated by like references in the various figures. In particular, the structural and/or functional features that are common among the various embodiments may have the same references and may dispose identical structural, dimensional and material properties.

For the sake of clarity, only the steps and elements that are useful for an understanding of the embodiments described herein have been illustrated and described in detail. In particular, the various applications that the described devices may have have not been detailed, the described embodiments being compatible with usual applications of ultrasonic imaging devices. Further, the properties (frequencies, shapes, amplitudes, etc.) of the electric excitation signals applied by the control circuit to the ultrasonic transducers have not been detailed, the described embodiments being compatible with the excitation signals currently used in ultrasonic imaging systems, which may be selected according to the considered application and in particular to the nature of the body to be analyzed and to the type of information which is desired to be acquired. Similarly, the various processings applied to the electric signals delivered by the ultrasonic transducers and read by the control circuit to extract useful information relative to the body to be analyzed have not been detailed, the described embodiments being compatible with processings currently used in ultrasonic imaging systems. Further, the forming of the ultrasonic transducers and of the control circuit of the described imaging devices has not been detailed, the detailed structure of these elements being within the abilities of those skilled in the art based on the indications of the present disclosure, by using known ultrasonic transducer and electronic circuit forming techniques.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

Unless specified otherwise, the expressions “around”, “approximately”, “substantially” and “in the order of” signify within 10%, and preferably within 5%.

FIG. 1 is a simplified electric diagram of an example of an ultrasonic imaging device 100.

Device 100 comprises at least one ultrasonic transducer 101, for example a transducer of CMUT (capacitive micromachined ultrasonic transducer) type. As a variant, transducer 101 may be an electro-capacitive transducer, a piezoelectric transducer, a crystal transducer, or any other type of ultrasonic transducer. Transducer 101 comprises two electrodes E1 and E2. When an appropriate excitation voltage is applied between electrodes E1 and E2, the transducer emits an ultrasonic acoustic wave. When the transducer receives an ultrasonic acoustic wave within a given wavelength range, it delivers between its electrodes E1 and E2 a voltage representative of the received wave.

Device 100 further comprises an electronic circuit 103 for controlling transducer 101. Control circuit 103 comprises a transmit circuit 110, adapted to applying an electric excitation signal to transducer 101 during a phase of emission of an ultrasonic wave, and a receive circuit 120 adapted to amplifying and digitizing an electric response signal generated by transducer 101 during a phase of reception of an ultrasonic wave (and more generally to conditioning the electric signals generated by transducer 101 during the receive phase).

Transmit circuit 110 comprises an output terminal n1 intended to be coupled, for example, to the electrode E2 of transducer 101. In this example, transmit circuit 110 comprises a pulse generator TX having an input node in intended to receive a logic control signal, and an output node out coupled, for example connected, to terminal n1. The input node in of pulse generator TX may be coupled, for example connected, to an output node of a logic control circuit, not shown, of the device. When the logic signal applied to input node in of generator TX is in a first state, generator TX delivers on its output node out a high-level voltage +HV and, when the logic signal applied to node in of generator TX is in a second state, generator TX delivers on its output node out a low-level voltage −HV. The output signal of pulse generator TX corresponds to a signal for exciting transducer 101, which may be applied to transducer electrode E2. The voltage level of this excitation signal may be relatively high, for example, in the order of from 10 to 100 volts peak to peak.

Receive circuit 120 comprises an input terminal n2 intended to be coupled, for example, connected, to the electrode E2 of transducer 101. In this example, receive circuit 120 comprises a receive amplifier 121, preferably low-noise (LNA), having an input node coupled, for example connected, to terminal n2. Further, in this example, receive circuit 120 comprises an analog-to-digital converter 123 (ADC) having an input node coupled to an output node of amplifier 121. Converter 123 is adapted to delivering digital samples quantized over a plurality of bits, for example over from 8 to 16 bits, representative of the amplitude of the input signal of the converter. In the example of FIG. 1, receive circuit 120 further comprises, between the output of amplifier 121 and the input of analog-to-digital converter 123, a time gain compensation circuit 125 (TGC). Circuit 125 is controllable to apply a time-variable analog gain to the output signal of amplifier 121, during a phase of reception of a return signal received by transducer 101. More particularly, during a phase of reception of a return ultrasonic wave by transducer 101, the gain applied by circuit 125 to the output signal of amplifier 121 progressively increases over time, and thus according to the depth of the explored area, to compensate for the attenuation of the ultrasonic signal by the explored medium. This enables to use at best the dynamic range of analog-to digital converter 123 all along the duration of the receive phase, and thus to limit the quantization noise introduced by the analog-to-digital converter 123, particularly for the most distant ultrasonic echoes. In the example of FIG. 1, reception circuit 120 further comprises an anti-aliasing analog filter 127 (AAF), for example, a low-pas filter, arranged between the output of amplifier 121 and the input of analog-to-digital converter 123. Anti-aliasing filter 127 is for example arranged between the output of time gain compensation circuit 125 and the input of converter 123. The receive circuit 120 of FIG. 1 further comprises, at the output of analog-to-digital converter 123, a digital correction circuit 129 (C), adapted to applying to the output signal of converter 123 a time-variable digital gain, aiming at compensating for the analog gain time variation applied by circuit 125 upstream of converter 123. The digital output signal of correction circuit 129 may for example be transmitted to a digital processing circuit, not shown.

In the shown example, control circuit 103 comprises a transmit switch SWTX having a first conduction node coupled, for example, connected, to the output terminal n1 of transmit circuit 110, and a second conduction node coupled, for example connected, to the electrode E2 of transducer 101. Further, in this example, control circuit 103 comprises a receive switch SWRX having a first conduction node coupled, for example connected, to the input terminal n2 of receive circuit 120, and a second conduction node coupled, for example connected, to the electrode E2 of transducer 101. Switches SWTX and SWRX may be maintained respectively on and off during transmit phases, and respectively off and on during receive phases. As a variant, switch SWTX may be omitted, the output terminal n1 of transmit circuit 110 being then directly connected to the electrode E2 of transducer 101. Further, as a variant, switch SWRX may be omitted, the input terminal n2 of receive circuit 120 then being directly connected to the electrode E2 of transducer 101. In this last case, a clipping circuit, not shown, may be provided between terminal n2 and a node of application of a reference potential of the circuit, for example, the ground, to protect receive circuit 120 during transmit phases, and particularly to avoid the destruction of the input amplifier 121 of receive circuit 120 under the effect of the electric excitation signal applied by pulse generator TX.

During transmit and/or receive phases, the electrode E1 of transducer 101 may be maintained at a reference potential of the device, for example the ground.

Although a single transducer 101 has been shown in FIG. 1, in practice, device 100 may comprise a large number of transducers, for example, identical or similar. In this case, electronic control circuit 103 may comprise a dedicated transmit circuit 110 and receive circuit 120 per ultrasonic transducer 101. As a variant, a same transmit circuit 110 and/or a same receive circuit 120 may be shared by a plurality of ultrasonic transducers 101.

A limitation of the electronic control circuit 103 described in relation with FIG. 1 lies in the difficulty of implementation and of driving of time gain compensation circuit 125.

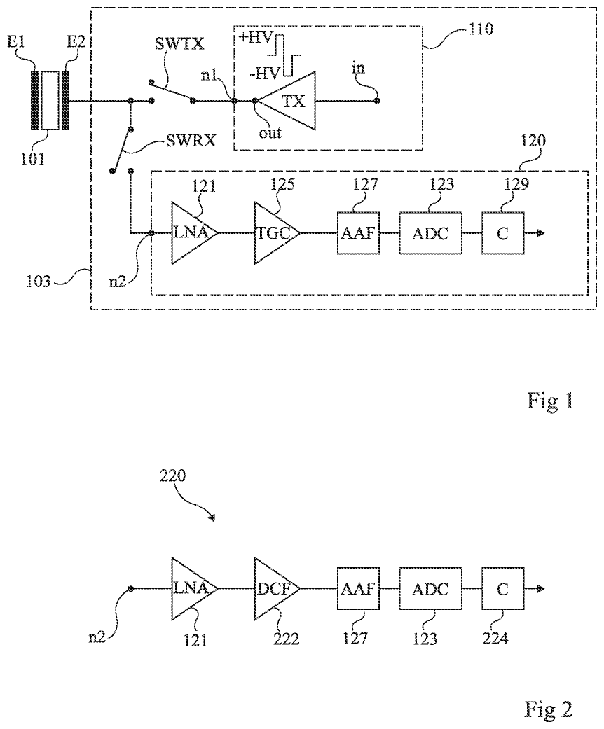

FIG. 2 schematically and partially illustrates, in the form of blocks, an example of a circuit for controlling an ultrasonic transducer according to an embodiment. The control circuit of FIG. 2 differs from the control circuit 103 previously described in relation with FIG. 1 mainly by the forming of its receive circuit 220. Thus, for simplification, only receive circuit 220, replacing the receive circuit 120 of FIG. 1, has been shown in FIG. 2.

The receive circuit 220 of FIG. 2 has elements common with the receive circuit 120 of FIG. 1. In the following description, these common elements will not be detailed again, and only the differences with respect to the receive circuit 120 of FIG. 1 will be highlighted.

Like the circuit 120 of FIG. 1, the receive circuit 220 of FIG. 2 comprises an input terminal n2 and a receive amplifier 121, preferably low-noise (LNA), having an input node coupled, for example connected, to terminal n2. Further, as in the example of FIG. 1, the receive circuit 220 of FIG. 2 comprises an analog-to-digital converter 123 (ADC) having an input node coupled to an output node of amplifier 121.

The receive circuit 220 of FIG. 2 differs from the receive circuit 120 of FIG. 1 mainly in that it does not comprise the analog time gain compensation circuit 125 (TGC) of circuit 120.

In the embodiment of FIG. 2, receive circuit 220 however comprises, between the input terminal n2 and the input of analog-to-digital converter 123, an analog dynamic range compression circuit 222 (DCF). In the shown example, circuit 222 has an input node coupled, for example, connected, to the output node of amplifier 121, and an output node coupled to the input node of analog-to-digital converter 123.

Conversely to the circuit 125 of FIG. 1, which has a time-variable linear transfer function, circuit 222 has a non-linear transfer function.

More particularly, by dynamic range compression circuit, there is here meant that circuit 222 has, for positive input signals, an increasing monotonous transfer function having its derivative (that is, the slope of the tangent to the curve) monotonously decreasing according to the amplitude of the input signal, over the entire input dynamic range of the circuit (that is, up to the saturation threshold of the circuit). The transfer function of circuit 222 is further symmetrical. Thus, circuit 222 more strongly amplifies signals having a relatively small amplitude (in absolute value) and more lightly amplifies signals having a relatively high amplitude (in absolute value).

In the example of FIG. 2, receive circuit 220 further comprises an anti-aliasing analog filter 127 (AAF), for example, a low-pass filter, arranged between the output of amplifier 121 and the input of analog-to-digital converter 123. Anti-aliasing filter 127 is for example arranged between the output of dynamic range compression circuit 222 and the input of converter 123.

The receive circuit of FIG. 2 further comprises, at the output of analog-to-digital converter 123, a digital correction circuit 224 (C), adapted to applying to an output signal of converter 123 a digital gain variable according to the amplitude of the signal, compensating for the analog gain variation applied by circuit 222 upstream of converter 123. The digital output signal of correction circuit 224 may for example be transmitted to a digital processing circuit, not shown.

In the receive circuit 220 of FIG. 2, dynamic range compression circuit 222 enables to more strongly amplify low-amplitude signals, that is, not only the most distant echoes as was already done by the time gain compensation circuit 125 of FIG. 1, but also light echoes originating from objects close to the transducer, which was not feasible by the time compensation circuit 125 of FIG. 1. This enables to limit the quantization noise introduced by analog-to-digital converter 123 for all the low-amplitude signals. For signals of stronger amplitude, the amplification is lighter, which amounts to increasing the quantization noise introduced by analog-to-digital converter 123, as was already done for close echoes with the time gain compensation circuit 125 of FIG. 1.

The reception circuit 220 of FIG. 2 further advantageously enables to do away with a time gain compensation circuit, relatively complex to implement and to control.

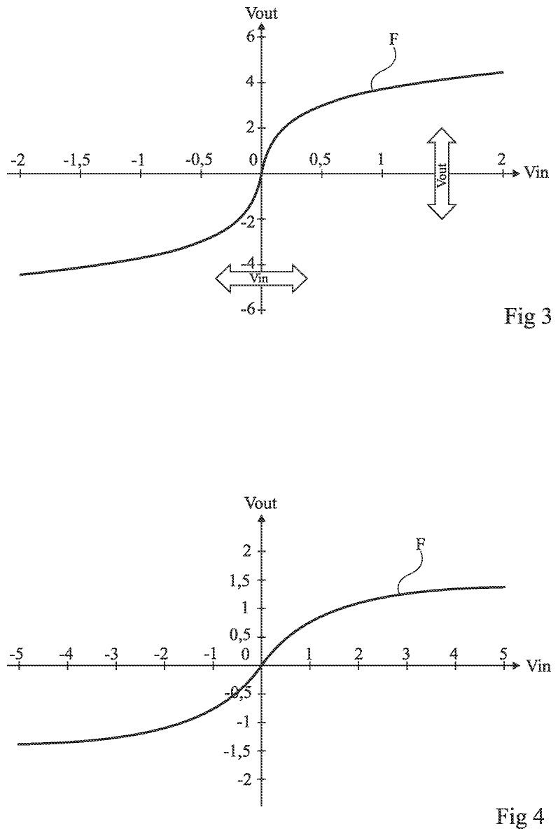

Examples of transfer functions capable of being implemented by circuit 222 will be described hereafter in relation with FIGS. 3 and 4. The forming of circuits 222 having such transfer functions or, more generally, any other transfer function adapted to implementing the desired dynamic range compression function, has not been detailed, the implementation of such non-linear amplification functions being within the abilities of those skilled in the art by using known electronic components, particularly components based on silicon, for example, transistors.

It should further be noted that the desired non-linear amplification function may be totally or partly implemented by input amplification circuit 121. Thus, in an alternative embodiment, not shown in FIG. 2, circuit 121 may be integrated to circuit 222, the input of circuit 222 being then directly coupled, for example, connected, to the input terminal n2 of receive circuit 220.

FIG. 3 is a diagram illustrating a first example of a transfer function capable of being implemented by the dynamic range compression circuit 222 of FIG. 2. In FIG. 3, there has been shown, on the axis of abscissas, a signal Vin corresponding to the input voltage applied to the input node of circuit 222 and, on the axis of ordinates, a signal Vout corresponding to the output voltage of circuit 222.

In this example, the transfer function F of circuit 222 a hyperbolic arcsine function (ASINH).

It should be noted that the hyperbolic arcsine function is a logarithmic function that may be expressed as follows:

ASINH(x)=log(x+\sqrt{x²−1}) [Math 1]

Such a function can easily be implemented by non-linear semiconductor components, for example components based on silicon, for example, transistors.

FIG. 4 is a diagram illustrating a second example of a transfer function capable of being implemented by the dynamic range compression circuit 222 of FIG. 2. As in FIG. 3, there has been shown in FIG. 4, on the axis of abscissas, a signal Vin corresponding to the input voltage applied to the input node of circuit 222 and, on the axis of ordinates, a signal Vout corresponding to the output voltage of circuit 222.

In this example, the transfer function F of circuit 222 is an arc tangent (ATAN) function, which also has the advantage of being relatively easily implementable based on existing electronic components, for example, semiconductor components based on silicon, for example, transistors.

More generally, any other dynamic range compression function may be used, for example, a logarithmic function, a sine function between −π/2 and +π/2, etc.

The digital correction function applied by circuit 224 downstream of analog-to-digital converter 123 may be selected to obtain, in fine, a linear representation of the acoustic signal received by the transducer. As an example, if F designates the transfer function applied by analog dynamic range compression circuit 222, the compensation function applied by digital correction circuit 224 may be a function of x=F⁻¹(y) type. The correction applied by circuit 224 may be a mathematically-determined function implemented by a digital processing circuit, for example of microprocessor, programmable logic circuit, etc. type. However, preferably, the correction implemented by circuit 224 is implemented by means of a lookup table previously determined during a phase of calibration of the device. This advantageously enables to correct all the possible distortions linked to the different components of receive circuit 220.

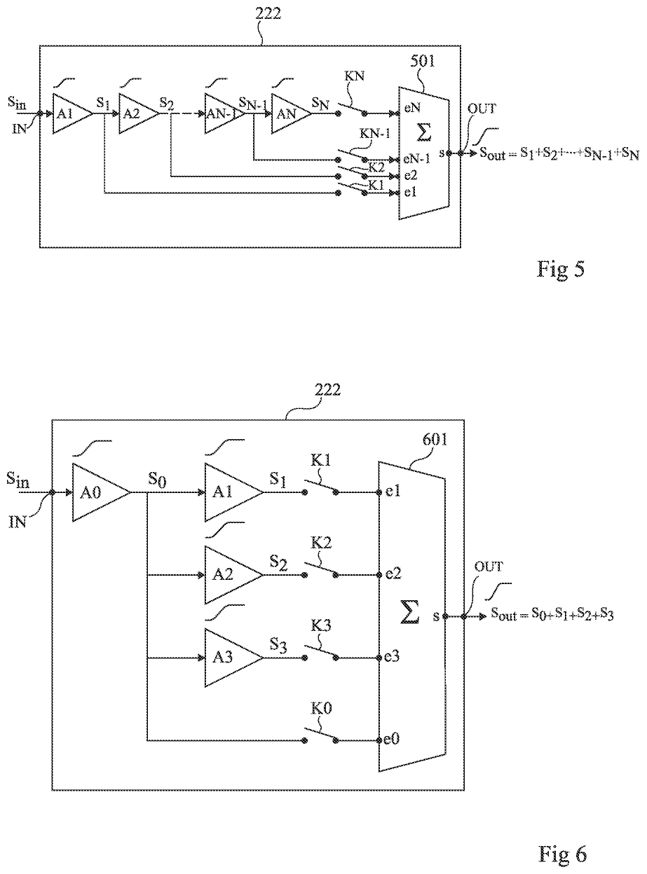

FIG. 5 schematically illustrates, in the form of blocks, an example of embodiment of the dynamic range compression circuit 222 of the receive circuit 220 of FIG. 2.

In this example, the dynamic range compression function is implemented by means of a plurality of linear response analog amplifiers coupled in series, and of an analog voltage adder.

More particularly, in the shown example, circuit 222 comprises N linear amplifiers A1, . . . AN, N being an integer greater than or equal to 2, and a voltage adder with N inputs e1, . . . eN.

Each amplifier Ai, i being an integer ranging from 1 to N, except for amplifier A1, has its input node coupled, for example connected, to the output node of the amplifier of previous rank Ai−1. Amplifier A1 has its input node coupled, for example connected, to the input node of circuit 222, designated with reference IN in FIG. 5.

Amplifiers A1, . . . AN further have their respective output nodes respectively coupled to the input nods e1, . . . eN of adder 501. In the shown example, the output nodes of amplifiers A1, . . . AN are coupled to the input nodes e1, . . . eN of the adder by respectively N switches K1, . . . KN. More particularly, in this example, each switch Ki has a first conduction node coupled, for example, connected, to the output node of the amplifier Ai of same rank i, and a second conduction node coupled, for example connected, to the input node ei of same rank i of voltage adder 501. As a variant, switches K1, . . . KN may be omitted, in which case each amplifier Ai has its output node directly coupled, for example, connected, to the input node ei of same rank i of adder 501.

In operation, circuit 222 receives on its input node IN a signal Sᵢₙ for example corresponding to the output signal of the amplifier 121 of FIG. 2. As a variant, the amplifier 121 of FIG. 2 may correspond to the amplifier A1 of the circuit 222 of FIG. 5, in which case input signal Sᵢₙ corresponds to the signal received on the input terminal n2 of the receive circuit 220 of FIG. 2.

Adder 501 delivers, on an output node s, a signal Sₒᵤₜ equal to the sum of the voltages S₁, . . . S_{N} applied to its input nodes e₁, . . . e_{N}.

Each amplifier Ai applies a substantially fixed gain over the entire extent of its dynamic range, up to its saturation threshold. The applied gain is for example the same for the N amplifiers A1, . . . AN, for example a gain in the order of 20 dB.

Considering all switches K1, . . . KN as being on, for input signals Sᵢₙ of small amplitude, the N amplifiers A1, . . . AN take part in the amplification of the signal. The contribution of the output signal S_{N} of amplifier AN to signal Sₒᵤₜ is then preponderating over the contributions of signals S₁, . . . S_{N-1}. When the saturation threshold of amplifier AN is reached, signal S_{N} no longer varies and remains blocked at its maximum value or saturation value. A linear amplification remains ensured by amplifiers A1, . . . A_{N-1}. The contribution of signal S_{N-1} to output signal Sₒᵤₜ becomes in particular significant, and preponderating over the contributions of signals S₁, . . . S_{N-2}. For input signals Sᵢₙ of high amplitude, when the saturation threshold of amplifier A2 has been reached, only amplifier A1 keeps on linearly amplifying the signal.

A non-linear transfer function Sₒᵤₜ=F(Sᵢₙ) is thus obtained, ensuring the desired dynamic range compression function.

As in the previous examples, the digital correction function applied by circuit 224 downstream of analog-to-digital converter 123 may be determined mathematically and implemented by a digital processing circuit for example of microprocessor, programmable logic circuit, etc. type. However, preferably, the correction implemented by circuit 224 is implemented by means of a lookup table previously determined during a phase of calibration of the device.

As a variant, in the case illustrated in FIG. 5 where the output nodes of amplifiers A1, . . . AN are coupled to the input nodes e1, . . . eN of the adder by respectively N switches K1, . . . KN, it may further be provided to implement a function of discrete time compensation of the transfer function of circuit 222. In particular, it may be provided, during a phase of reception of an ultrasonic wave, to successively turn on switches K1 to KN during the receive phase, to increase in successive stages the maximum gain available according to the explored depth. It should be noted that as compared with a continuous time compensation of the type implemented by the circuit 125 of FIG. 1, these discrete (staged) adjustment function is relatively simple to implement.

FIG. 6 schematically illustrates, in the form of blocks, another example of embodiment of the dynamic range compression circuit 222 of the reception circuit 220 of FIG. 2.

Here again, the dynamic range compression function is implemented by means of a plurality of analog linear response amplifiers coupled in series, and of an analog voltage adder.

More particularly, in this example, circuit 222 comprises N+1 linear amplifiers A0, A1, . . . AN, N being an integer greater than or equal to 2, and a voltage adder 601 with N+1 inputs e0, e1, . . . eN. In the shown example, N is equal to 3, the described embodiments being of course non-limited to this specific case.

Amplifier A0 has its input node coupled, for example connected, to the input node IN of circuit 122. Amplifier A0 for example corresponds to the amplifier 121 of the receive circuit 220 of FIG. 2, which is then integrated in dynamic range compression circuit 222.

Each amplifier Ai, i being an integer ranging from 1 to N, has its input node coupled, for example connected, to the output node of amplifier A0. Amplifiers A1, . . . AN further have their respective output nodes respectively coupled to the input nods e1, . . . eN of adder 601. In the shown example, the output nodes of amplifiers A1, . . . AN are coupled to the input nodes e1, . . . eN of the adder by respectively N switches K1, . . . KN. More particularly, in this example, each switch Ki has a first conduction node coupled, for example, connected, to the output node of the amplifier Ai of same rank i, and a second conduction node coupled, for example connected, to the input node ei of same rank i of voltage adder 601. As a variant, switches K1, . . . KN may be omitted, in which case each amplifier Ai has its output node directly coupled, for example, connected, to the input node ei of same rank i of adder 601. Further, in this example, amplifier A0 has its output node coupled to the input node e0 of adder 601 via a switch K0. As a variant, switch K0 may be omitted, in which case the output node of amplifier A0 may be directly coupled, for example connected, to the input node e0 of adder 601.

In operation, circuit 222 receives on its input node IN a signal Sᵢₙ.

Adder 601 delivers, on an output node s, a signal Sₒᵤₜ equal to the sum of the voltages S₁, . . . S_{N} applied to its input nodes e₁, . . . e_{N}.

In the example of FIG. 6, each amplifier Ai, i being an integer ranging from 1 to N, has a gain higher than that of the amplifier of previous rank Ai−1.

By considering all switches K0, K1, . . . KN as being on, for input signals Sᵢₙ of small amplitude, the N amplifiers A0, A1, . . . AN take part in the amplification of the signal. The contribution of the output signal S_{N} of amplifier AN to signal Sₒᵤₜ is however preponderating over the contributions of signals S₀, S₁, . . . S_{N-1}. When the saturation threshold of amplifier AN has been reached, signal S_{N} no longer varies and remains blocked at its maximum value or saturation value. A linear amplification remains ensured by amplifiers A0, A1, . . . A_{N-1}. The contribution of signal S_{N-1} to output signal Sₒᵤₜ becomes in particular significant, and preponderating over the contributions of signals S₀, . . . S_{N-2}. For input signals Sᵢₙ of high amplitude, when the saturation threshold of amplifier A1 has been reached, only amplifier A0 keeps on linearly amplifying the signal.

A non-linear transfer function Sₒᵤₜ=F(Sᵢₙ) is thus obtained, ensuring the desired dynamic range compression function.

As in the previous examples, the digital correction function applied by circuit 224 downstream of analog-to-digital converter 123 may be determined mathematically and implemented by a digital processing circuit for example of microprocessor, programmable logic circuit, etc. type. However, preferably, the correction implemented by circuit 224 is implemented by means of a lookup table previously determined during a phase of calibration of the device.

As a variant, in the case illustrated in FIG. 6 where the output nodes of amplifiers A0, A1, . . . AN are coupled to the input nodes a0, e1, . . . eN of the adder by respectively N+1 switches K0, K1, . . . KN, it may further be provided to implement a function of discrete time compensation of the transfer function of circuit 222. In particular, it may be provided, during a phase of reception of an ultrasonic wave, to successively turn on switches K0 to KN during the receive phase, to increase in successive stages the maximum gain available according to the explored depth.

Various embodiments and variants have been described. Those skilled in the art will understand that certain features of these various embodiments and variants may be combined, and other variants will occur to those skilled in the art. In particular, the described embodiments are not limited to the examples described hereabove of embodiment of the dynamic range compression circuit 222 of receive circuit 220. More generally, those skilled in the art will be capable of providing other implementations enabling to obtain the desired analog dynamic range compression function.

1. A circuit for controlling an ultrasonic transducer, comprising a receive circuit having an input terminal intended to be coupled to an electrode of the transducer, said receive circuit comprising an analog dynamic range compression circuit.

2. The circuit according to claim 1, wherein the receive circuit further comprises an analog-to-digital converter, the analog dynamic range compression circuit having an input node coupled to the input terminal of the receive circuit and an output node coupled to an input node of the analog-to-digital converter.

3. The circuit according to claim 2, further comprising, at the output of the analog-to-digital converter, a digital correction circuit configured to apply to the output signal of the analog-to-digital converter a digital gain variable according to the amplitude of the signal, compensating for the analog gain variation applied by the analog dynamic range compression circuit.

4. The circuit according to claim 1, wherein the analog dynamic range compression circuit is a non-linear amplification circuit having a symmetrical transfer function, said transfer function being, for positive input signals, an increasing monotonous function having its derivative monotonously decreasing according to the amplitude of the input signal.

5. The circuit according to claim 1, wherein the dynamic range compression circuit has a transfer function of hyperbolic arcsine, arc tangent, log, or sine type.

6. The circuit according to claim 1, wherein the dynamic range compression circuit comprises a plurality of analog amplifiers and an adder of analog voltages.

7. The circuit according to claim 6, wherein the analog amplifiers are coupled in series, each analog amplifier having an output node coupled to a corresponding input node of the voltage adder.

8. The circuit according to claim 7, wherein each analog amplifier has its output node coupled to the corresponding input node of the voltage adder via a switch.

9. The circuit according to claim 7, wherein the analog amplifiers are linear amplifiers and all have substantially the same gain.

10. The circuit according to claim 6, wherein the analog amplifiers are connected by their respective input nodes, each analog amplifier having an output node coupled to a corresponding input node of the voltage adder.

11. The circuit according to claim 10, wherein each analog amplifier has its output node coupled to the corresponding input node of the voltage adder via a switch.

12. The circuit according to claim 11, wherein the analog amplifiers are linear amplifiers and all have different gains.
